(19) United States
(12) Patent Application Publication
(10) Pub. No.: US 2019/0277454 A1
(43) Pub. Date: Sep. 12, 2019

(54) LIGHT-EMITTING DEVICE

(71) Applicant: TOYODA GOSEI CO., LTD., Kiyosu-shi (JP)

(72) Inventors: Yuhki KAWAMURA, Kiyosu-shi (JP); Satoshi WADA, Kiyosu-shi (JP); Kento HAYASHI, Kiyosu-shi (JP); Masaaki OSAWA, Kiyosu-shi (JP); Masao KAMIYA, Kiyosu-shi (JP)

(21) Appl. No.: 16/227,918

(22) Filed: Dec. 20, 2018

(30) Foreign Application Priority Data
Mar. 8, 2018 (JP) 2018-041506

(51) Int. Cl. F21K 9/64; F21V 7/28; H01S 5/00; H01S 5/022; F21V 31/00; F21K 9/68

(52) U.S. Cl. CPC F21K 9/64; F21V 7/28; H01S 5/0071; F21Y 2115/30; H01S 5/02296; F21V 31/005; F21K 9/68; H01S 5/02212

(57) ABSTRACT

A light-emitting device includes a semiconductor laser element arranged in a first space, a resin member arranged in a second space, a light transmitting member that transmits light emitted from the semiconductor laser element, the light transmitting member being included in a wall separating the first space from the second space; and a wavelength-converting member that absorbs the light emitted from the semiconductor laser element and passing through the light transmitting member and converts wavelength of the light. The first space and the second space are isolated from each other so as not to exchange any gas therebetween.

The present application is based on Japanese patent application No. 2018-041506 filed on Mar. 8, 2018, the entire contents of which are incorporated herein by reference.

### BACKGROUND OF THE INVENTION

### 1. Field of the Invention

The invention relates to a light-emitting device.

### 2. Related Art

A light-emitting device is known in which a wall having a light-passing hole at the center is provided in a housing enclosing a semiconductor laser element (laser diode), and a space accommodating the semiconductor laser element and a space accommodating a wavelength-converting member are partitioned by the wall (see, e.g., JP 5083205 B).

The light-emitting device described in JP 5083205 B has high light extraction efficiency since only a small portion of light wavelength-converted by the wavelength-converting member returns through the light-passing hole to the space accommodating the semiconductor laser element (the amount of return light is very little), and the majority is reflected by a hemispherical light reflective surface formed in the space accommodating the wavelength-converting member.

### SUMMARY OF THE INVENTION

The light-emitting device of JP 5083205 B is constructed such that the spaces inside the housing (or package) communicate with each other. In this device, if a resin-containing reflective material for improving light extraction efficiency or a resin-containing adhesive for fixing the wavelength-converting member etc. is arranged or used in the package, a surface of the semiconductor laser element may get contaminated with a gas vaporized from a resin material (e.g., siloxane gas generated from a silicone resin), causing a problem in laser oscillation. Thus, the light-emitting device may have the above problem in arranging a resin-containing member inside the housing thereof.

It is an object of the invention to provide a light-emitting device that is high in light extraction efficiency and prevents the contamination of the semiconductor laser element caused by the gas generated from the resin member inside the housing.

According to an embodiment of the invention, a light-emitting device defined by [1] to [7] below can be provided.

[1] A light-emitting device, comprising:

a semiconductor laser element arranged in a first space;

a resin member arranged in a second space;

a light transmitting member that transmits light emitted from the semiconductor laser element, the light transmitting member being included in a wall separating the first space from the second space; and

a wavelength-converting member that absorbs the light emitted from the semiconductor laser element and passing through the light transmitting member and converts wavelength of the light,

wherein the first space and the second space are isolated from each other by the wall and the light transmitting member so as not to exchange any gas therebetween.

[2] The light-emitting device according to [1], wherein the light transmitting member comprises a glass.

[3] The light-emitting device according to [1] or [2], wherein the wall comprises the light transmitting member and a plate-shaped support member supporting the light transmitting member, and a distance from the height of the semiconductor laser element to the height of the bottom surface of the light transmitting member is larger than to the height of the bottom surface of the support member.

[4] The light-emitting device according to [3], wherein a contact surface between the light transmitting member and the support member is inclined so as to widen from the first space toward the second space.

[5] The light-emitting device according to any one of [1] to [4], wherein the resin member comprises an adhesive for fixing the wavelength-converting member.

[6] The light-emitting device according to any one of [1] to [5], wherein the resin member comprises a reflective material formed on an inner surface in the second space.

[7] The light-emitting device according to any one of [1] to [6], wherein the resin member comprises a silicone-based resin.

### Effects of the Invention

According to an embodiment of the invention, a light-emitting device can be provided that is high in light extraction efficiency and prevents the contamination of the semiconductor laser element caused by the gas generated from the resin member inside the housing.

### BRIEF DESCRIPTION OF THE DRAWINGS

Next, the present invention will be explained in more detail in conjunction with appended drawings, wherein:

FIG. 1A is a vertical cross-sectional view showing a light-emitting device in the first embodiment;

FIG. 1B is an enlarged cross-sectional view showing a light transmitting member and a portion of a first cap close to the light transmitting member in the light-emitting device;

FIG. 2 is a vertical cross-sectional view showing a preferable example of a method for fixing the light transmitting member to the first cap;

FIGS. 3A to 3C are vertical cross-sectional views showing examples of the shape of the light transmitting member;

FIG. 4 is a vertical cross-sectional view showing a modification of the light-emitting device in the first embodiment;

FIG. 5 is a vertical cross-sectional view showing another modification of the light-emitting device in the first embodiment;

FIG. 6 is a vertical cross-sectional view showing a light-emitting device in the second embodiment; and

FIG. 7 is a vertical cross-sectional view showing a modification of the light-emitting device in the second embodiment.

### DESCRIPTION OF THE PREFERRED EMBODIMENTS

### First Embodiment

Configuration of Light-Emitting Device

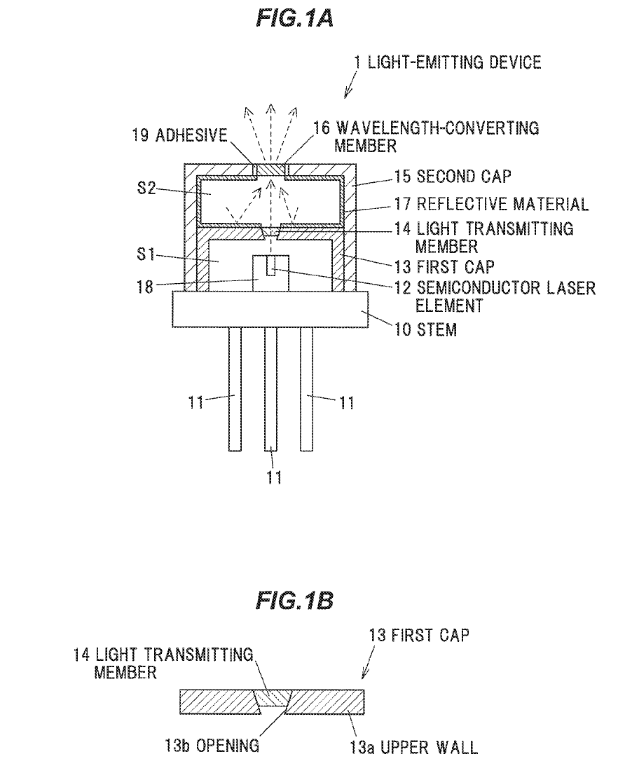

FIG. 1A is a vertical cross-sectional view showing a light-emitting device 1 in the first embodiment. The light-emitting device 1 has a form called CAN package, and is provided with a stem 10 having electrode pins 11, a semiconductor laser element 12 mounted on the stem 10, a first cap 13 enclosing the semiconductor laser element 12, a light transmitting member 14 fitted to an opening on the first cap 13, a second cap 15 arranged on the outer side of the first cap 13, and a wavelength-converting member 16 fitted to an opening on the second cap 15.

A first space S1, which is a space inside the first cap 13 and accommodating the semiconductor laser element 12, is enclosed by the stem 10, the first cap 13 and the light transmitting member 14 and is airtightly sealed.

Meanwhile, a second space S2 is a space inside the second cap 15 and outside the first cap 13, and resin members are arranged in the second space S2. The resin members are members containing a resin and are, e.g., a reflective material 17 and an adhesive 19 (described later).

The first space S1 is airtightly sealed as described above, and is spatially isolated from the second space S2 so that gases are not exchanged. In this configuration, since a gas generated from the resin members arranged in the second space S2 substantially does not enter the first space S1, it is possible to prevent contamination of the semiconductor laser element 12 with such gas.

Some kind of gas is generated from any resin regardless of the type thereof. When the semiconductor laser element 12 is exposed to such gas, the surface is contaminated and this may cause a problem in laser oscillation. Particularly siloxane gas generated by vaporization of silicone-based resin severely contaminates the semiconductor laser element 12. Therefore, when the resin member arranged in the second space S2 contains a silicone-based resin, the effect of preventing contamination of the semiconductor laser element 12 described above becomes of more importance.

FIG. 1B is an enlarged cross-sectional view showing the light transmitting member 14 and a portion of the first cap 13 close to the light transmitting member 14 in the light-emitting device 1. The first cap 13 has an opening 13b on its upper wall 13a, and the light transmitting member 14 is fitted to the opening 13b. The upper wall 13a of the first cap 13 and the light transmitting member 14 fitted thereto form a wall which isolates the first space S1 from the second space S2.

The stem 10 is formed of a metal material or an insulating material with a high thermal conductivity. The electrode pins 11 include an electrode pin connected to the n-pole of the semiconductor laser element 12, an electrode pin connected to the p-pole and, if required, an electrode pin connected to, e.g., a temperature sensor (not shown) for measuring temperature of the semiconductor laser element 12.

The semiconductor laser element 12 functions as an excitation light source for the wavelength-converting member 16. The semiconductor laser element 12 in a state of being arranged on a base 18 is mounted on the stem 10.

The wavelength of the semiconductor laser element 12 is not specifically limited and is appropriately selected according to, e.g., the material (absorption wavelength) of the wavelength-converting member 16 and color of light extracted from the light-emitting device 1. When, e.g., the semiconductor laser element 12 emits blue light and the wavelength-converting member 16 exhibits yellow fluorescence, light which can be extracted from the light-emitting device 1 is white light as a mixture of yellow fluorescence and a portion of blue light extracted without being wavelength-converted by the wavelength-converting member 16.

The first cap 13 is placed open-side down and fixed to the stem 10 so that the semiconductor laser element 12 is housed therein. The first cap 13 is formed of a material with which high airtightness can be obtained, such as stainless steel or iron.

The light transmitting member 14 is formed of a material which transmits light emitted from the semiconductor laser element 12. The light transmitting member 14 is located on an optical axis of the semiconductor laser element 12. The light emitted from the semiconductor laser element 12 can travel from the first space S1 to the second space S2 through the light transmitting member 14.

The light transmitting member 14 is formed of a glass such as borate-based glass, silicate-based glass or sapphire glass, or a resin such as polycarbonate or acrylic. In this regard, glass is more preferable as the material of the light transmitting member 14 than a resin generating a gas which potentially could contaminate the semiconductor laser element 12. The planar shape of the light transmitting member 14 is typically a square, but may be a circle or a polygon other than square.

To fix the light transmitting member 14 to the first cap 13, it is preferable to avoid use of a resin-containing adhesive.

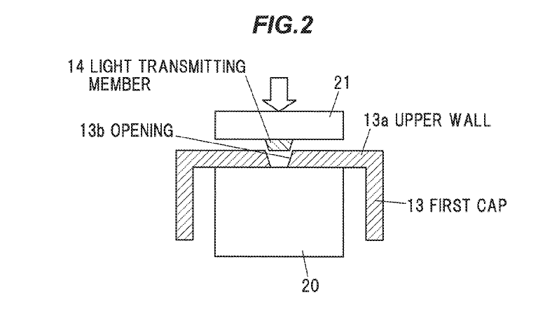

FIG. 2 is a vertical cross-sectional view showing a preferable example of a method for fixing the light transmitting member 14 to the first cap 13. In the method shown in FIG. 2, firstly, a heating element 20 is brought into contact with the periphery of the opening 13b of the first cap 13 from the back side of the first cap 13 (from the first space S1 side) to heat the periphery of the opening 13b of the first cap 13. The heating element 20 here is a member formed of a metal, etc., and heated to a temperature not less than a melting point of the light transmitting member 14.

Then, the light transmitting member 14 is pressed into the opening 13b from the front side of the first cap 13 by a pressing machine 21 in the state the temperature of the periphery of the opening 13b of the first cap 13 is not less than the melting point of the light transmitting member 14. This causes a portion of the light transmitting member 14 in contact with a side surface of the opening 13b to melt. The molten portion solidifies as the temperature drops, and the light transmitting member 14 is thereby fixed inside the opening 13b of the first cap 13.

In the method shown in FIG. 2, the melting point of the first cap 13 needs to be higher than the melting point of the light transmitting member 14 so that the first cap 13 does not melt during heating.

Meanwhile, in the method shown in FIG. 2, if the light transmitting member 14 comes into contact with the heating element 20 when pushing the light transmitting member 14 into the opening 13b of the first cap 13, the light transmitting member 14 may melt and deform. Therefore, to prevent the light transmitting member 14 from coming into contact with the heating element 20, a distance from the height of the semiconductor laser element 12 to the height of the bottom surface of the light transmitting member 14 is preferably larger than to the height of the bottom surface of the upper wall 13a of the first cap 13 which is a plate-shaped support member supporting the light transmitting member 14.

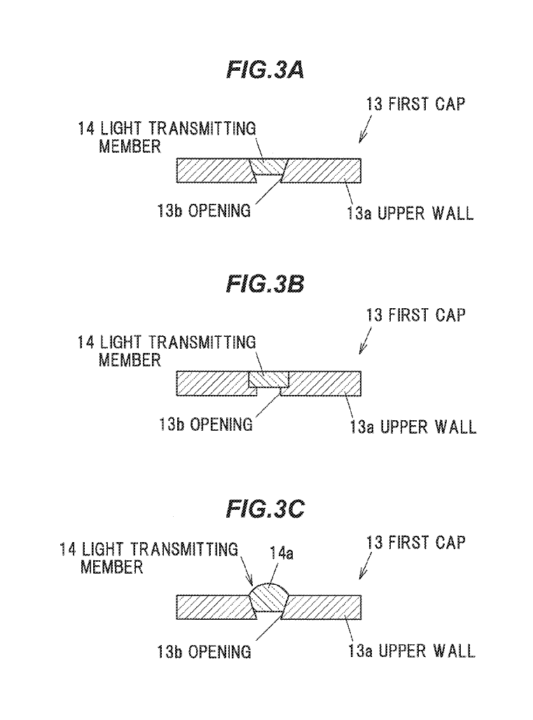

FIGS. 3A to 3C are vertical cross-sectional views showing examples of the shape of the light transmitting member 14. In the example shown in FIG. 3A, a contact surface between the light transmitting member 14 and the upper wall 13a is inclined so as to widen from the first space S1 toward the second space S2. Thus, it is possible to easily fix the light transmitting member 14 in the intended position only by pushing the light transmitting member 14 into the opening 13b from the front side of the first cap 13.

In the example shown in FIG. 3B, a level difference is provided on the side surface of the opening 13b so that the diameter of the opening 13b is smaller on the first space S1 side than the second space S2 side. The light transmitting member 14 is fitted to the opening 13b in a region on the second space S2 side. Thus, it is possible to easily fix the light transmitting member 14 in the intended position only by pushing the light transmitting member 14 into the opening 13b from the front side of the first cap 13.

In the example shown in FIG. 3C, the light transmitting member 14 has a dome-shaped lens region 14a which protrudes toward the second space S2 beyond the upper wall 13a of the first cap 13. Light emitted from the semiconductor laser element 12 is focused by the lens region 14a, allowing improvement in light extraction efficiency.

A DBR (Distributed Bragg Reflector) film may be provided on a surface of the light transmitting member 14 on the first space S1 side or on the second space S2 side.

The DBR film can transmit light emitted from the semiconductor laser element 12 and reflect fluorescence emitted from the wavelength-converting member 16.

The second cap 15 is placed open-side down and fixed to the stem 10 so that the side surface of the first cap 13 is covered. The second space S2 is a space surrounded by the upper wall of the first cap 13, the second cap 15 and the wavelength-converting member 16.

The second cap 15 may be formed of the same material as the first cap 13, but can be formed of a material with high heat dissipation such as aluminum by placing significance on dissipation of heat from the wavelength-converting member 16 since the space inside the second cap 15 (the second space S2) does not need to be airtight unlike the first cap 13. Thus, the second cap 15 is preferably formed of a material with a higher thermal conductivity than the first cap 13.

Light incident on the wavelength-converting member 16 and scattered backward in the second space S2 is mostly reflected by the upper wall 13a of the first cap 13 serving as a wall isolating the first space S1 from the second space S2 and is less likely to return to the first space S1. Thus, light absorbed by the semiconductor laser element 12, the base 18 or the inner surface of the first cap 13, etc., is very little, allowing the light-emitting device 1 to have high light extraction efficiency.

A reflective material 17 is preferably provided on an inner surface in the second space S2 to increase reflectance of the inner surface in the second space S2 and thereby further improve light extraction efficiency of the light-emitting device 1.

The reflective material 17 is a film formed of a resin containing a reflective filler. A silicon-based resin or an epoxy-based resin, etc., can be used as the resin constituting the reflective material 17. Particles of a highly reflective material such as TiO₂, BaSO₄, ZnO, BaCO₃ or SiO₂ can be used as the reflective filler.

The reflective material 17 is a resin member containing a resin, and a gas which potentially could contaminate the semiconductor laser element 12 is generated from the reflective material 17 due to vaporization. However, since the first space S1 and the second space S2 are spatially isolated from each other as described above, the gas generated from the reflective material 17 does not enter the first space S1.

When the upper wall 13a of the first cap 13 is covered with the reflective material 17, the entire first cap 13 may be formed of the material used to form the light transmitting member 14. In this case, since the first cap 13 also serves as the light transmitting member, there is no need of the light transmitting member 14 and the first cap 13 does not have the opening 13b. The reflective material 17 covers the upper wall 13a excluding a region on and near the optical axis.

The wavelength-converting member 16 is fitted to an opening on the upper wall of the second cap 15. The wavelength-converting member 16 is typically located on the optical axis of the semiconductor laser element 12.

The wavelength-converting member 16 is a member containing a phosphor which absorbs light emitted from the semiconductor laser element 12 and emits fluorescence. The wavelength-converting member 16 is, e.g., a member containing phosphor particles in a base material such as alumina, glass or resin, or a sintered phosphor.

The phosphor contained in the wavelength-converting member 16 is not specifically limited and may be, e.g., a yellow phosphor such as YAG (Yttrium aluminum garnet) phosphor, an a-SiAlON phosphor or BOS (Barium orthosilicate) phosphor, or may be a mixture of a green phosphor such as β-SiAlON phosphor and a red phosphor such as (Ca,Sr)₂Si₅N₈:Eu,CaAlSiN₃:Eu.

The planar shape of the wavelength-converting member 16 is typically a square, but may be a circle or a polygon other than square.

It is possible to further reduce the return light from the second space S2 to the first space S1 by configuring the light transmitting member 14 so that a surface on the second space S2 side has a smaller area than the area of the wavelength-converting member 16.

The wavelength-converting member 16 may be fixed to the second cap 15 by an adhesive 19 containing a resin, as shown in FIG. 1. The adhesive 19 is preferably a highly thermally conductive adhesive so that heat of the wavelength-converting member 16 can be effectively transferred to the second cap 15. The adhesive 19 is, e.g., a silicone-based adhesive containing a highly thermally conductive filler.

The adhesive 19 is a resin member containing a resin, and a gas which potentially could contaminate the semiconductor laser element 12 is generated from the adhesive 19 due to vaporization. However, since the first space S1 and the second space S2 are spatially isolated from each other as described above, the gas generated from the adhesive 19 does not enter the first space S1.

Configuration of Light-Emitting Device in Modification

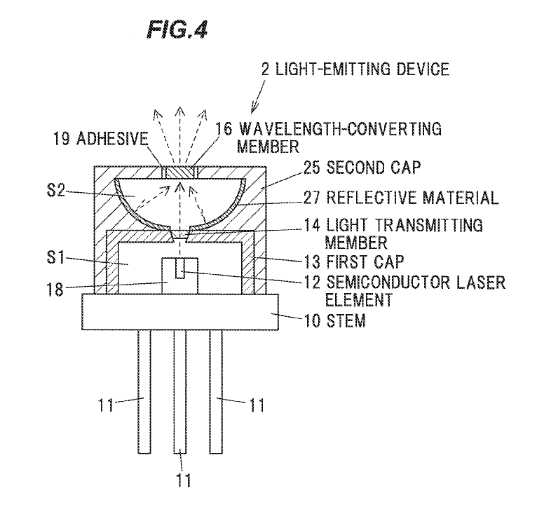

FIG. 4 is a vertical cross-sectional view showing a light-emitting device 2 which is a modification of the light-emitting device 1 in the first embodiment.

The light-emitting device 2 is configured that an inner wall in the second space S2 defined by a second cap 25 (an inner surface except an upper surface) has a curved surface. Thus, light scattered backward by the wavelength-converting member 16 easily returns to the wavelength-converting member 16, allowing the light-emitting device 2 to have high light extraction efficiency.

In addition, a reflective material 27 may be formed on the curved inner wall in the second space S2 defined by the second cap 25, as shown in FIG. 4. In this case, it is possible to increase reflectance of the inner wall in the second space S2 and thereby further improve light extraction efficiency of the light-emitting device 2.

The reflective material 27 is a resin member containing a resin, and is formed of the same material as the reflective material 17 in the first embodiment.

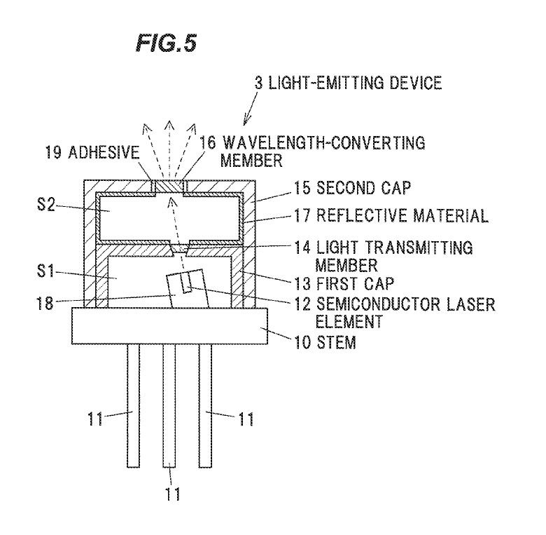

FIG. 5 is a vertical cross-sectional view showing a light-emitting device 3 which is another modification of the light-emitting device 1 in the first embodiment.

The light-emitting device 3 is configured that the direction of the optical axis of the semiconductor laser element 12 is inclined with respect to the bottom surface (light incidence surface) of the wavelength-converting member 16. In this configuration, since the light emitted from the semiconductor laser element 12 is not incident at a right angle on the light incidence surface of the wavelength-converting member 16, specular reflection components in light are less likely to return to the first space S1 through the light transmitting member 14. This prevents absorption of light by the semiconductor laser element 12, the base 18 or the inner surface of the first cap 13, etc., allowing the light-emitting device 3 to have high light extraction efficiency.

### Second Embodiment

The second embodiment is different from the first embodiment in that the light-emitting device is a surface-mount device (SMD). The same members as those in the first embodiment are denoted by the same reference numerals and the explanation thereof will be omitted or simplified.

Configuration of Light-Emitting Device

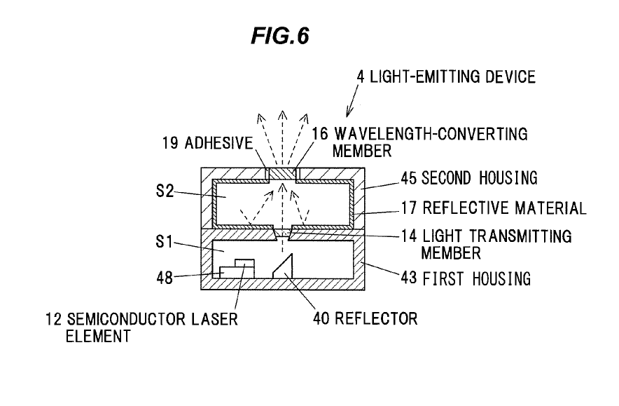

FIG. 6 is a vertical cross-sectional view showing a light-emitting device 4 in the second embodiment. The light-emitting device 4 has a form called SMD, and is provided with the semiconductor laser element 12, a reflector 40 for reflecting light emitted from the semiconductor laser element 12, a first housing 43 enclosing the semiconductor laser element 12 and the reflector 40, the light transmitting member 14 fitted to an opening on the first housing 43, a second housing 45 arranged on the first housing 43, and the wavelength-converting member 16 fitted to an opening on the second housing 45.

The first space S1, which is a space inside the first housing 43 and accommodating the semiconductor laser element 12, is enclosed by the first housing 43 and the light transmitting member 14 and is airtightly sealed.

Meanwhile, the second space S2 is a space inside the second housing 45, and resin members are arranged in the second space S2. The resin members are members containing a resin and are, e.g., the reflective material 17 or the adhesive 19.

The first space S1 is airtightly sealed as described above, and is spatially isolated from the second space S2 so that gases are not exchanged. In this configuration, since a gas generated from the resin members arranged in the second space S2 substantially does not enter the first space S1, it is possible to prevent contamination of the semiconductor laser element 12 with such gas.

The first housing 43 has an opening on its upper wall, and the light transmitting member 14 is fitted to the opening. The upper wall of the first housing 43 and the light transmitting member 14 fitted thereto form a wall which isolates the first space S1 from the second space S2.

The semiconductor laser element 12 functions as an excitation light source for the wavelength-converting member 16. The semiconductor laser element 12 in a state of being arranged on a base 48 is housed in the first housing 43.

The first housing 43 is formed of a material with which high airtightness can be obtained, such as stainless steel or iron, in the same manner as the first cap 13 in the first embodiment.

The opening of the first housing 43 has the same shape and the same other features as those of the opening 13b of the first cap 13 in the first embodiment, and the light transmitting member 14 can be fitted to the opening of the first housing 43 by the method used to fit the light transmitting member 14 to the opening 13b of the first cap 13.

The light emitted from the semiconductor laser element 12 is reflected by the reflector 40 such as mirror and then travels from the first space S1 to the second space S2 through the light transmitting member 14.

The second housing 45 is fixed onto the upper wall of the first housing 43. The second space S2 is a space surrounded by the upper wall of the first housing 43, the second housing 45 and the wavelength-converting member 16.

The second housing 45 can be formed of the same material as the second cap 15 in the first embodiment.

Light incident on the wavelength-converting member 16 and scattered backward in the second space S2 is mostly reflected by the upper wall of the first housing 43 serving as a wall isolating the first space S1 from the second space S2 and is less likely to return to the first space S1. Thus, light absorbed by the semiconductor laser element 12, the base 48 or the inner surface of the first housing 43, etc., is very little, allowing the light-emitting device 4 to have high light extraction efficiency.

The reflective material 17 is preferably provided on the inner surface in the second space S2 to increase reflectance of the inner surface in the second space S2 and thereby further improve light extraction efficiency of the light-emitting device 4.

The reflective material 17 is a resin member containing a resin, and a gas which potentially could contaminate the semiconductor laser element 12 is generated from the reflective material 17 due to vaporization. However, since the first space S1 and the second space S2 are spatially isolated from each other as described above, the gas generated from the reflective material 17 does not enter the first space S1.

The wavelength-converting member 16 is fitted to an opening on the upper wall of the second housing 45. The wavelength-converting member 16 may be fixed to the second housing 45 by the adhesive 19 containing a resin.

The adhesive 19 is a resin member containing a resin, and a gas which potentially could contaminate the semiconductor laser element 12 is generated from the adhesive 19 due to vaporization. However, since the first space S1 and the second space S2 are spatially isolated from each other as described above, the gas generated from the adhesive 19 does not enter the second space S2.

Configuration of Light-Emitting Device in Modification

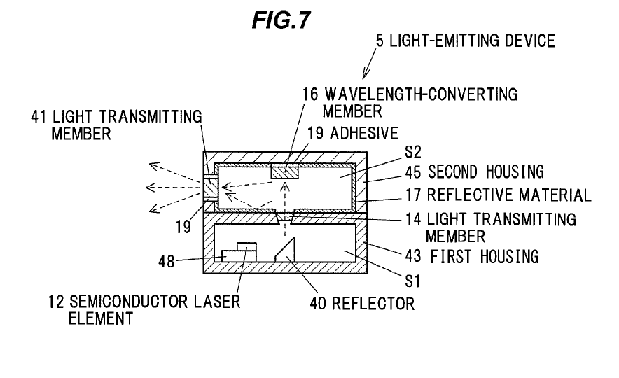

FIG. 7 is a vertical cross-sectional view showing a light-emitting device 5 which is a modification of the light-emitting device 4 in the second embodiment.

The light-emitting device 5 is configured that light is extracted laterally. The wavelength-converting member 16 is fixed, by the adhesive 19, to the upper surface in the second space S2 defined by the second housing 45. Light wavelength-converted by the wavelength-converting member 16 and light scattered without being absorbed by the wavelength-converting member 16 are extracted through a light transmitting member 41 which is fixed, by the adhesive 19, to an opening on a side portion of the second housing 45.

The light transmitting member 41 is formed of a material transmitting light emitted from the semiconductor laser element 12 and light wavelength-converted by the wavelength-converting member 16, and is formed of, e.g., a glass such as borate-based glass, silicate-based glass or sapphire glass, or a resin such as polycarbonate or acrylic.

### Effects of the Embodiments

According to the first and second embodiments, it is possible to provide a light-emitting device which has high light extraction efficiency and can prevent contamination of a semiconductor laser element with a gas generated from a resin member inside a housing.

Although the embodiments of the invention have been described, the invention is not intended to be limited to the embodiments, and the various kinds of modifications can be implemented without departing from the gist of the invention. In addition, the constituent elements in the embodiments can be arbitrarily combined without departing from the gist of the invention.

In addition, the invention according to claims is not to be limited to the embodiments. Further, please note that all combinations of the features described in the embodiments are not necessary to solve the problem of the invention.

What is claimed is:

1. A light-emitting device, comprising:
a semiconductor laser element arranged in a first space;
a resin member arranged in a second space;
a light transmitting member that transmits light emitted from the semiconductor laser element, the light transmitting member being included in a wall separating the first space from the second space; and
a wavelength-converting member that absorbs the light emitted from the semiconductor laser element and passing through the light transmitting member and converts wavelength of the light,
wherein the first space and the second space are isolated from each other so as not to exchange any gas therebetween.

2. The light-emitting device according to claim 1, wherein the light transmitting member comprises a glass.

3. The light-emitting device according to claim 1, wherein the wall comprises the light transmitting member and a plate-shaped support member supporting the light transmitting member, and a distance from the height of the semiconductor laser element to the height of the bottom surface of the light transmitting member is larger than to the height of the bottom surface of the support member.

4. The light-emitting device according to claim 3, wherein a contact surface between the light transmitting member and the support member is inclined so as to widen from the first space toward the second space.

5. The light-emitting device according to claim 1, wherein the resin member comprises an adhesive for fixing the wavelength-converting member.

6. The light-emitting device according to claim 1, wherein the resin member comprises a reflective material formed on an inner surface in the second space.

7. The light-emitting device according to claim 1, wherein the resin member comprises a silicone-based resin.
